(19) United States
(12) Patent Application Publication
(10) Pub. No.: US 2025/0372583 A1
(43) Pub. Date: Dec. 4, 2025

(54) LIGHT EMITTING DEVICE

(71) Applicant: Bridgelux Optoelectronics (Xiamen) Co., Ltd., Xiamen (CN)

(72) Inventors: JINGQIONG ZHANG, Xiamen (CN); JING CHEN, Xiamen (CN); XIAOLING HUANG, Xiamen (CN); GUOHENG QIN, Xiamen (CN); DEBING HUANG, Xiamen (CN); CONGLIN WU, Xiamen (CN)

(21) Appl. No.: 19/026,722

(22) Filed: Jan. 17, 2025

(30) Foreign Application Priority Data
Jun. 3, 2024 (CN) 202410716474X

(51) Int. Cl. H01L 25/075; F21K 9/00; F21Y 113/17; F21Y 115/10; H05B 45/20; H10H 29/24; H10H 29/851

(52) U.S. Cl. CPC H01L 25/0753; F21K 9/00; H10H 29/24; H10H 29/8512; F21Y 2113/17; F21Y 2115/10; H05B 45/20

(57) ABSTRACT

A light emitting device is provided. The light emitting device includes a blue light unit, configured to emit blue light; a green light unit, configured to emit green light; a red light unit, configured to emit red light; and a warm white light unit, configured to emit warm white light. A dominant wavelength of the warm white light is in a range from 570 nm to 600 nm. A color coordinate of the warm white light unit and a color coordinate of the red light unit are respectively located at opposite sides of the Planckian locus. The blue light unit, the green light unit, the red light unit and the warm white light unit are configured to cooperate to emit mixed white light and are configured to adjust a color temperature of the mixed white light.

### CROSS-REFERENCE TO RELATED APPLICATION

This application claims priority to Chinese patent application No. CN 202410716474.X, filed to China National Intellectual Property Administration (CNIPA) on Jun. 3, 2024, which is herein incorporated by reference in its entirety.

### TECHNICAL FIELD

The present disclosure relates to the technical field of lighting, and particularly to a light emitting device.

### BACKGROUND

At present, there are some intelligent lighting lamps in the market, which generally include multiple light-emitting units with different colors, such as a red-green-blue light-emitting unit and a cold and warm white light-emitting unit. These intelligent lighting lamps are generally called RGBCW intelligent lamps. The RGBCW intelligent lamps can achieve the dimming of colored light and white light. The red-green-blue light-emitting unit, namely RGB light-emitting unit, is generally responsible for dimming of colored light. The cold and warm white light-emitting unit, namely CW light-emitting unit, is generally responsible for adjusting a color temperature of mixed white light. With the development of light emitting diode (LED) technology, the applicant introduced a more compact intelligent lighting device in a Chinese patent application CN202310698509.7 (with a publication number NO. CN117239038A), which includes four different light-emitting units, but can realize the same dimming function of colored light and white light as the traditional RGBCW intelligent lamps. On this basis, the applicant further improved the intelligent lighting device in the Chinses patent application to enhance the quality of white light.

### SUMMARY

In order to solve the technical problem of how to give consideration to the dimming of colored light and white light and generating mixed white light with higher quality in compact lamps, an embodiment of the present disclosure provides a light emitting device. The light emitting device includes blue, green and red light units, and a warm white light unit with a dominant wavelength in a range from 570 nm to 600 nm. The light emitting device can realize the output of colored light and multi-color temperature mixed white light through the four-color light-emitting unit, and can obtain mixed white light with a higher color rendering index (CRI) at multiple color temperatures.

An embodiment of the present disclosure provides a light emitting device, which includes: a blue light unit, configured to emit blue light; a green light unit, configured to emit green light; a red light unit, configured to emit red light; and a warm white light unit, configured to emit light with a dominant wavelength being greater than or equal to 570 nm and less than or equal to 600 nm. The blue light unit, the green light unit, the red light unit and the warm white light unit are configured to cooperate to emit mixed white light and are configured to adjust a color temperature of the mixed white light.

Another embodiment of the present disclosure provides a light emitting device, which includes: a blue light unit, configured to emit blue light; a green unit, configured to emit green light; a red light unit, configured to emit red light; and a warm white light unit, configured to emit warm white light, where a color coordinate of the warm white light is expressed as W(x_{W}, y_{W}), where 0.4≤x_{W}≤0.5 and 0.4≤y_{W}≤0.5, and the color coordinate W(x_{W}, y_{W}) of the warm white light is located above a Planckian locus. The blue light unit, the green light unit, the red light unit and the warm white light unit are configured to cooperate to emit mixed white light and are configured to adjust a color temperature of the mixed white light.

According to the technical solutions provided by the embodiments of the present disclosure, a compact intelligent light-emitting device is realized by arranging four light-emitting units, and the compact intelligent light-emitting device can generate colored light with different colors and mixed white light with different color temperatures (i.e., a color temperature of the mixed white light can be adjusted) by using fewer types of light sources. In addition, through limiting a dominant wavelength of the light emitted by the warm white light unit or through limiting a color coordinate of the light emitted by the warm white light unit, the mixed white light with various color temperatures emitted by the light emitting device is close to a black body locus (that is, a color tolerance is less than 5 standard deviation of color matching (SDCM)) and has a good CRI by adjusting a current ratio of the four light-emitting units independently controlled in a process of adjusting different color temperatures of the mixed white light.

### BRIEF DESCRIPTION OF DRAWINGS

In order to explain the technical solutions of the embodiments of the present disclosure more clearly, accompanying drawings needed in the description of the embodiments will be briefly introduced below. Apparently, the accompanying drawings in the following description are only some embodiments of the present disclosure. For the skilled in the art, other drawings can be obtained according to these accompanying drawings without creative work.

FIG. 1 illustrates a schematic structural diagram of a light emitting device according to an embodiment of the present disclosure.

FIG. 2 illustrates a schematic color gamut diagram in an international commission on illumination (CIE) color space of the light emitting device shown in FIG. 1.

FIG. 3 illustrates a schematic diagram of spectral distribution of a warm white light unit shown in FIG. 1.

FIG. 4A, FIG. 4B, FIG. 5A and FIG. 5B illustrate schematic diagrams of spectral distribution of mixed white light emitted by the light emitting device shown in FIG. 1 in different embodiments.

### DETAILED DESCRIPTION OF EMBODIMENTS

The technical solutions in the embodiments of the present disclosure will be clearly and completely described with reference to the accompanying drawings below. Apparently, the described embodiments are merely part of embodiments of the disclosure, but not the whole embodiment. Based on the described embodiments in the present disclosure, all other embodiments obtained by the skilled in the art without creative work belong to the scope of protection of the present disclosure.

It should be noted that terms “including” and “having” in the description and claims of the present disclosure, as well as any variations thereof, are intended to cover exclusive inclusion. Definition of numerical range is understood to include both ends unless it is explicitly stated that it does not include both ends. For example, a dominant wavelength in a range from 570 nm to 600 nm means that the dominant wavelength may be any value greater than or equal to 570 nm and less than or equal to 600 nm.

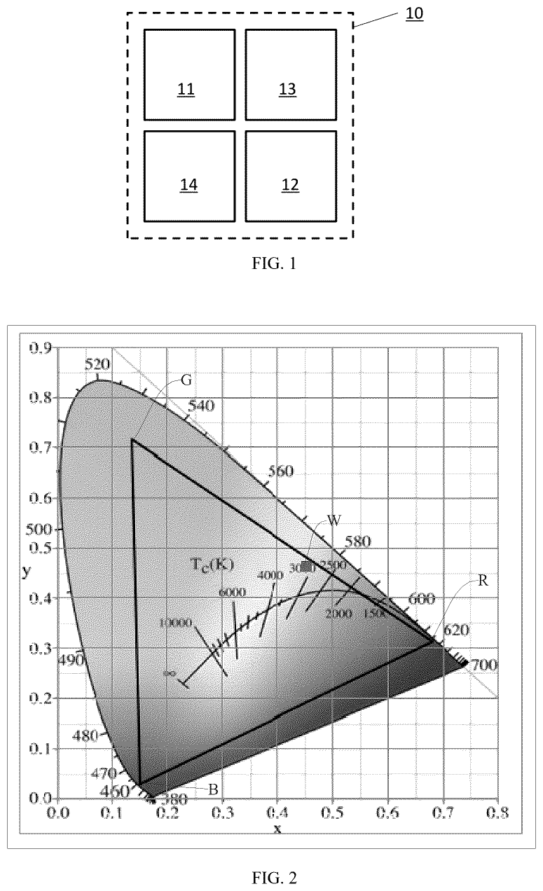

As illustrated in FIG. 1 and FIG. 2, an embodiment of the present disclosure provides a light emitting device 10. The light emitting device 10 includes a blue light unit 11, a green light unit 12, a red light unit 13 and a warm white light unit 14, as shown in FIG. 1. The blue light unit 11 is configured to emit blue light, the green light unit 12 is configured to emit green light, the red light unit 13 is configured to emit red light, and the warm white light unit 14 is configured to emit warm white light. The four light emitting units, i.e., the blue light unit 11, the green light unit 12, the red light unit 13 and the warm white light unit 14, are electrically independent. In some embodiments, the light emitting device 11 can modulate different colors by using the blue light unit 11, the green light unit 12 and the red light unit 13 as a blue light source, a green light source and a red light source, respectively. In a CIE color space (such as CIE 1931 color space), a color coordinate of the blue light unit 11 is expressed by a point B(x_{B}, y_{B}), and a blue light purity of the blue light unit 11 is greater than 0.96, where 0.1≤x_{B}≤0.2, and 0≤y_{B}≤0.1; a color coordinate of the green light unit 12 is expressed by a point G(x_{G}, y_{G}), and a green light purity of the green light unit 12 is greater than 0.7, where 0.1≤x_{G}≤0.2, and 0.65≤y_{G}≤0.75; and a color coordinate of the red light unit 13 is expressed by a point R(x_{R}, y_{R}), and a red light purity of the red light unit 13 is greater than 0.9, where 0.63≤x_{R}≤0.7, and 0.3≤y_{R}≤0.35. A region defined by the three points R, G, and B is a color gamut of colors that can be modulated by the light emitting device 10, and the NTSC (a color gamut space standard developed by the National Television Systems Committee) color gamut of the light emitting device 10 is greater than 105% in the present disclosure.

In other embodiments of the present disclosure, the blue light unit 11, the green light unit 12, the red light unit 13 and the warm white light unit 14 are configured to cooperate to emit mixed white light, which is close to a black body locus, and are also configured to adjust a color temperature of the mixed white light. In particular, in order to make the mixed white light closer to the black body locus in a color temperature adjustment range of 1800 kelvins (K) to 6500 K, for example, to make a color tolerance of the mixed white light be smaller than 4 SDCM, a color coordinate of the warm white light unit 14 is expressed as W(x_{W}, y_{W}), where 0.4≤x_{W}≤0.5 and 0.4≤y_{W}≤0.5, and the color coordinate W(x_{W}, y_{W}) of the warm white light is located above a Planckian locus. As such, a region surrounded by the color coordinates of the blue light unit 11, the green light unit 12, the red light unit 13 and the warm white light unit 14 can cover a color temperature adjustment range from 1800 K to 2700 K in the Planckian locus, the color coordinates of the warm white light unit 14 and the red light unit 13 are located at opposite sides of the Planckian locus, and the light emitting device 10 can output the mixed white light with a lower color temperature through the cooperation of a luminous intensity ratio between the red light unit 13 and the warm white light unit 14. Luminous intensities of the four light-emitting units can be adjusted independently, so that it is more convenient to adjust the colors or a color temperature of light outputted by the light emitting device 10. In summary, the light emitting device 10 provided by the embodiment of the present disclosure achieves the technical effects of reducing a total number of light sources and still achieving the adjustment of colors and a color temperature of mixed white light by arranging the four light-emitting units.

In an embodiment of the present disclosure, in order to realize high-quality mixed white light more easily, a dominant wavelength of the blue light emitted by the blue light unit 11 of the present disclosure is in a range from 455 nm to 465 nm, the blue light unit 11 includes a first blue light emitting diode (LED) chip (i.e., a first blue chip) with a dominant wavelength being greater than or equal to 455 nm and less than or equal to 465 nm, and a light-transmitting adhesive is selectively covered on the first blue chip to protect the first blue chip. A dominant wavelength of the green light emitted by the green light unit 12 is in a range from 515 nm to 530 nm, and the green light unit 12 includes a first green LED chip (i.e., a first green chip) with a dominant wavelength being greater than or equal to 515 nm and less than or equal to 530 nm, and a light-transmitting adhesive is selectively covered on the first green chip to protect the first green chip. Generally speaking, if it is only intended to achieve a higher color gamut, a red light unit will be preferred to participate in the color adjustment, but the red light unit 13 of the present disclosure needs to participate in the adjustment of mixed white light, especially the mixed white light with a lower color temperature such as 1800 K. Therefore, in order to make the mixed white light be closer to black body locus, a dominant wavelength of the red light emitted by the red light unit 13 of the present disclosure is in a range from 615 nm to 630 nm, and the red light unit 13 includes a blue LED chip (also referred to as a second blue chip) and red phosphors configured to covert blue light into the red light. Various technical solutions can be used to realize the dominant wavelength of the red light from 615 nm to 630 nm, which will be further described later.

It is well known that, blue light, green light and red light with higher color purity cannot modulate white light with a relatively continuous spectrum and close to a black body locus. In order to make the final obtained mixed white light be closer to the black body locus in the color temperature adjustment range from 1800 K to 6500 K, the warm white light unit 14 needs to have a certain luminous intensity in a visible light range and supplement light emitted by the blue light unit 11, the green light unit 12 and the red light unit 13. Extensive experimental research had shown that when a dominant wavelength of the warm white light emitted by the warm white light unit 14 is greater than or equal to 570 nm and less than or equal to 600 nm, through different current configurations, the warm white light can be combined with the blue light, the green light and the red light with higher color purity, to generate the mixed white light, which is closer to black body locus and has a relatively continuous spectrum, and a color tolerance of the mixed white light is smaller than 5 SDCM. Further, in a color temperature adjustment range from 1800 K to 6500 K, a color tolerance of the mixed white light emitted by the light emitting device 10 is smaller than 4 and a CRI of the mixed white light is greater than 90.

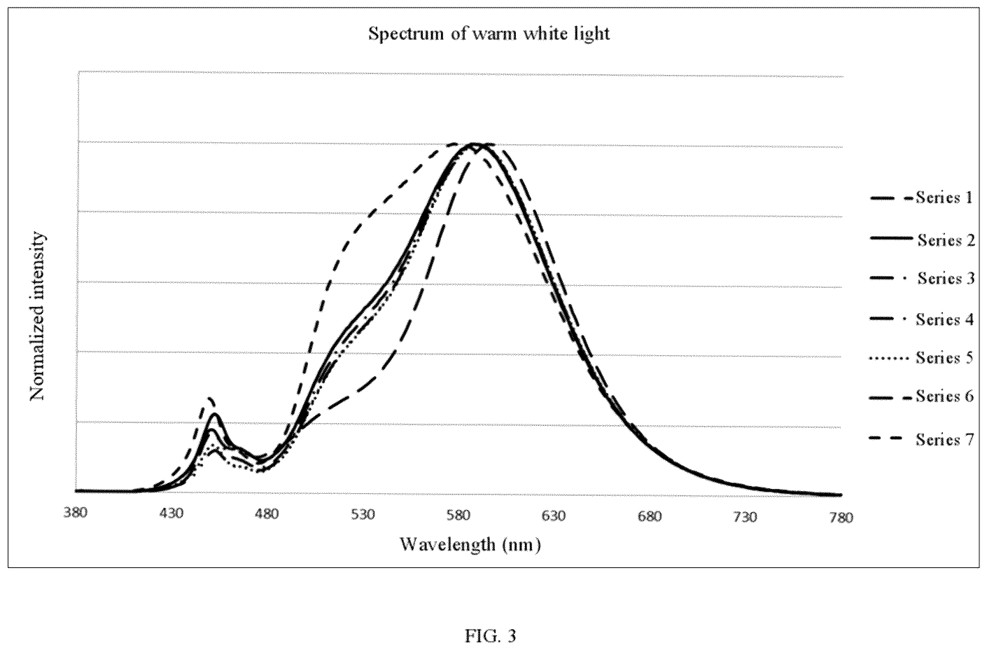

In an embodiment, spectral distribution of the warm white light unit 14 is shown in FIG. 3. The warm white light unit 14 can, for example, excite a fluorescent material by a blue chip to emit warm white light with a peak (Wp) wavelength of 570 nm to 600 nm and an FWHM of 90 nm to 140 nm. Specifically, the blue chip (i.e., a third blue chip) included in the warm white light unit 14 preferably has a dominant wavelength of 445 nm to 460 nm, and the used fluorescent material includes, for example, yellow-green phosphors with a main emission band of 530 nm to 550 nm and red phosphors with a main emission band of 600 nm to 625 nm. In the spectrum of the warm white light unit 14, there is a blue light peak Wp_{B} in a blue band, and an intensity ratio of the blue light peak Wp_{B} to the warm white light peak Wp (that is, a normalized intensity of a peak in the blue band) is between 10% and 30%, thereby making it easier for the light emitting device 10 to adjust the mixed white light to have a lower color temperature. Because the adjustment of red light of the mixed white light depends more on the red light unit 13 in the process of adjusting the color temperature of mixed white light, CRI(Ra)≤75 is preferred for the warm white light unit 14. In this way, the light emitting device 10 can realize the mixed white light with a lower color temperature and closer to the black body locus through the cooperation of a luminous intensity ratio between the red light unit 13 and the warm white light unit 14.

In addition, as shown in the different embodiments of warm white light with a dominant wavelength between 570 nm and 600 nm in series 1 to series 7 of FIG. 3, when a luminous intensity of the warm white light unit 14 at a wavelength of 530 nm is 25%-75% of a peak wavelength intensity of the warm white light unit 14, the 530 nm intensity ratio of warm white light unit 14 is higher, it can provide more green light energy, and a luminous intensity of the green light unit 12 with higher purity can be reduced when the mixed white light is adjusted, as such, high-quality mixed white light can be realized more stably and easily. Under the design of this spectral distribution, the light emitting device 10 can provide mixed white light with a CRI being greater than or equal to 90 in the color temperature adjustment range from 1800 K to 6500 K by adjusting the luminous intensities of different light emitting units. Furthermore, when a relative luminous intensity of the warm white light unit 14 at the wavelength of 530 nm is set to be greater than or equal to 45% and less than or equal to 55%, in a color temperature adjustment range of 2200 K to 6500 K the light emitting device 10 can provide mixed white light with a CRI being greater than or equal to 95 more stably and easily.

The red light unit 13 mentioned above preferably emits the red light with the dominant wavelength of 615 nm to 630 nm, and may include any one of various combinations of a blue chip and different red phosphors. For example, in some embodiments, the red light unit 13 may include a blue chip with a dominant wavelength of 445 nm to 460 nm and a combination of narrow-band nitride red phosphors and fluoride red phosphor. The narrow-band nitride red phosphors in the present disclosure may be red phosphors with an FWHM of 60 nm to 70 nm, such as (SrCa)AlSiN₃ (SCASN), and the fluoride red phosphors may be Mn⁴⁺-activated K₂TiF₆ (KSF), K₂GeF₆ (KGF), and K₂TiF₆ (KTF). The blue chip excites the narrow-band nitride red phosphors and the fluoride red phosphors to emit the red light with a peak wavelength of 632±2 nm and an FWHM being less than 10 nm, that is, the dominant wavelength of the red light can fall between 615 nm and 630 nm, thus further achieving the goal of the present disclosure. In this embodiment, the fluoride red phosphors have a higher wavelength conversion efficiency, which can improve the brightness of the red light unit 13, but the fluoride red phosphors has a poorer absorption of blue light, so the red light with higher purity cannot be achieved by simply using fluoride, which is not conducive to the adjustment of the color of the light emitting device 10, and the excess blue light that cannot be absorbed will also affect the freedom of adjustment of the blue light of the mixed white light in the process of adjust the color temperature of the mixed white light, so the narrow-band nitride red phosphors are used in combination to absorb the excess blue light, and when a normalized intensity of the blue light of mixed white light is less than 0.3, a purity of the red light unit 13 is greater than 0.9.

In other embodiments, the red light unit 13 may include a blue chip with a dominant wavelength of 445 nm to 460 nm and wide-band nitride red phosphors. The wide-band nitride red phosphors may be red phosphors with an FWHM of 70 nm to 90 nm, such as Eu²⁺-activated (SrCa)AlSiN₃ (SCASN), CaAlSiN₃ (CASN), and (BaSr)₂Si₅N₈ (BSSN). The blue chip excites the wide-band nitride red phosphors to emit red light with a purity being greater than 0.9, and when the peak wavelength of the red light is 634±5 nm and an FWHM of the red light is in a range from 70 nm to 90 nm, the dominant wavelength of the red light can be realized to fall between 615 nm and 630 nm, thus further achieving the goal of the present disclosure. It should be noted that the narrow-band SCASN and the wide-band SCASN mentioned here are nitride red phosphors with the same elemental composition, and the difference is that a Sr content of the narrow-band SCASN is relatively more than the wide-band SCASN.

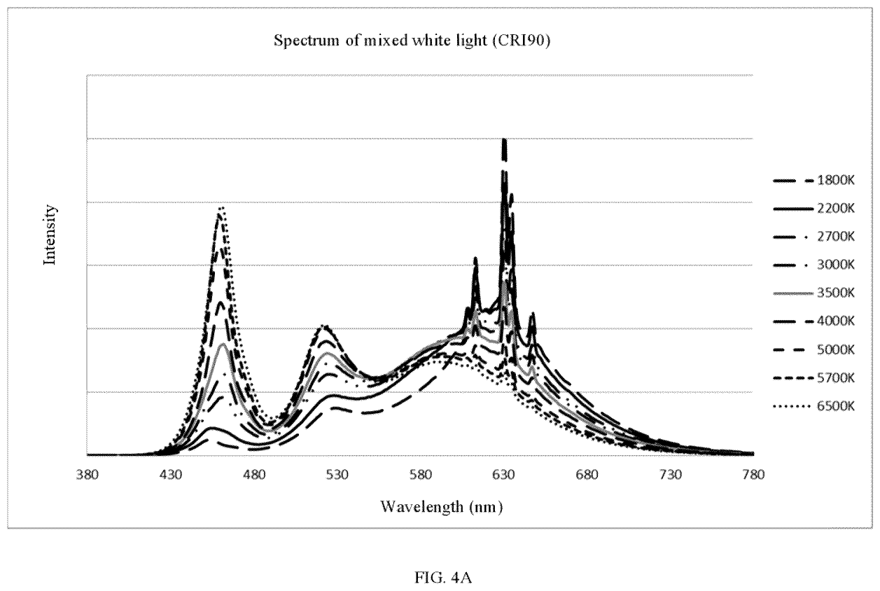

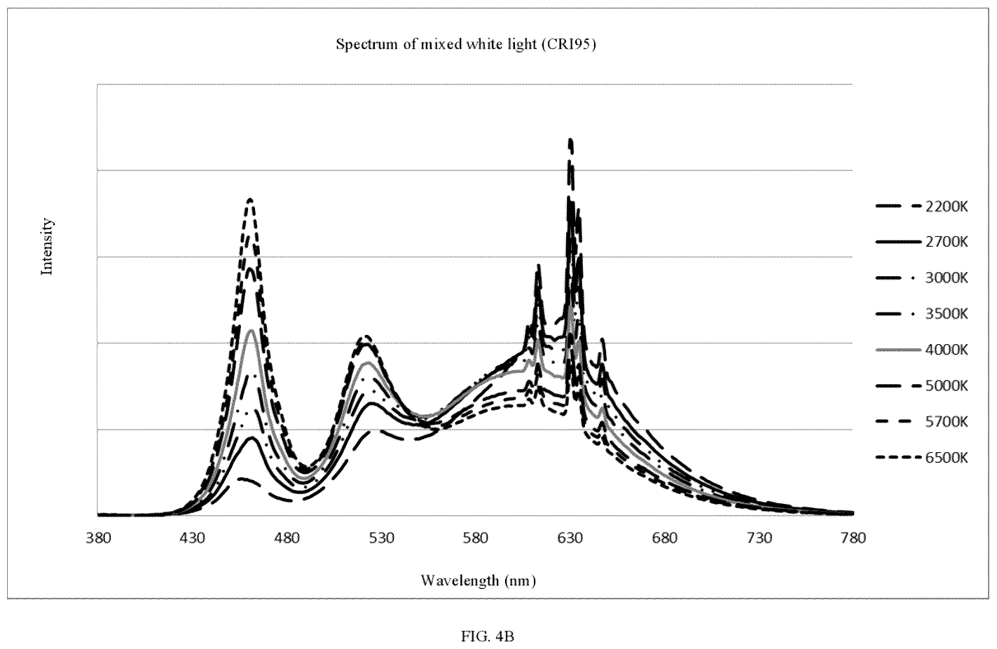

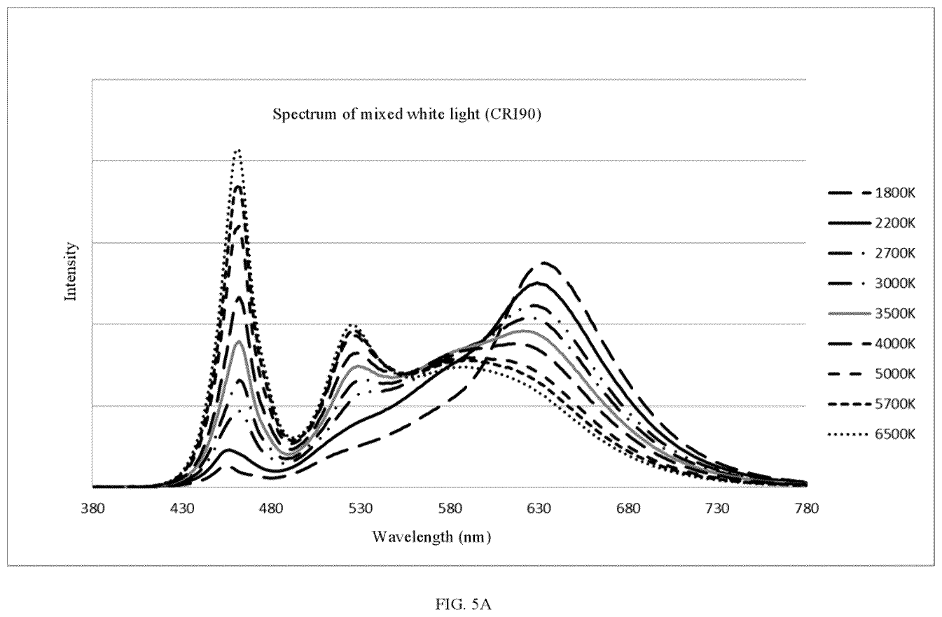

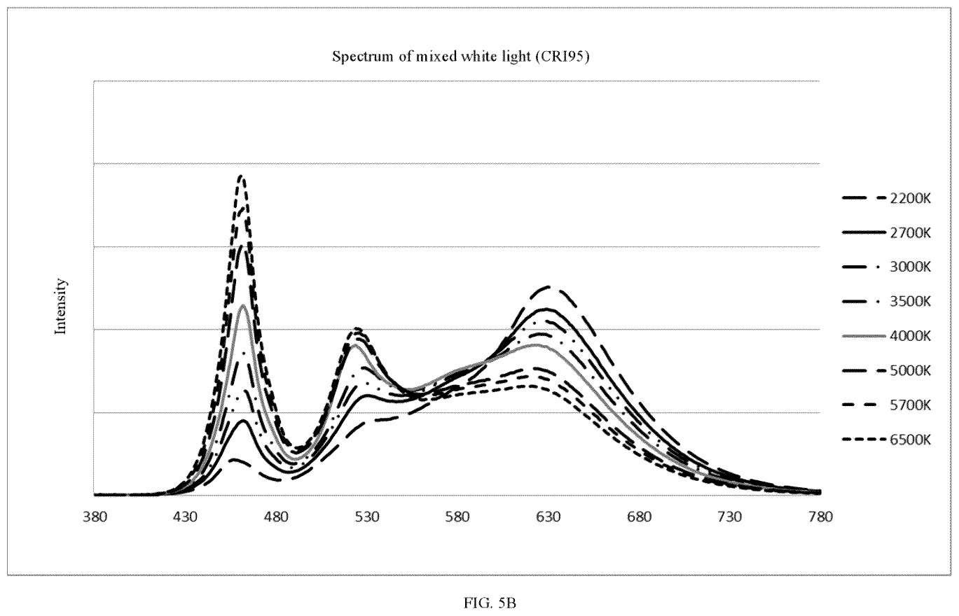

As illustrated in FIG. 4A and FIG. 5A, FIG. 4A and FIG. 5A illustrate schematic diagrams of spectral distribution of high-quality mixed white light with CRI being greater than 90 at different color temperatures in a color temperature adjustment range of 1800 K to 6500 K through current configuration of light emitting devices 10 with different red light units 13. Specifically, FIG. 4A illustrates spectral distribution of the light emitting device 10 with a red light unit 13 including a blue chip with a dominant wavelength of 445 nm to 460 nm and a combination of narrow-band nitride red phosphors and fluoride red phosphor, and FIG. 5A illustrates spectral distribution of the light emitting device 10 with the red light unit 13 including a blue chip with a dominant wavelength of 445 nm to 460 nm and wide-band nitride red phosphors. It should be noted that, the blue light unit 11, the green light unit 12, and the warm white light unit 14 of the light emitting device 10 corresponding to FIG. 4A are the same as the blue light unit 11, the green light unit 12, and the warm white light unit 14 of the light emitting device 10 corresponding to FIG. 5A. According to the present disclosure, by designing four different light emitting units, various current configurations can be adopted, so that the effects of color adjustment and color temperature adjustment as well as higher CRI can be achieved. There are various solutions for current proportion distribution, for example, FIG. 4B and FIG. 5B illustrate schematic diagrams of spectral distribution of mixed white light with CRI being greater than or equal to 95 at different color temperatures in a color temperature adjustment range of 2200 K to 6500 K through different current configuration of light emitting devices 10 with different red light units 13. Specifically, FIG. 4B illustrates spectral distribution of the light emitting device 10 with a red light unit 13 including a blue chip with a dominant wavelength of 445 nm to 460 nm and a combination of narrow-band nitride red phosphors and fluoride red phosphor, and FIG. 5B illustrates spectral distribution of the light emitting device 10 with the red light unit 13 including a blue chip with a dominant wavelength of 445 nm to 460 nm and wide-band nitride red phosphors. It should be noted that, the blue light unit 11, the green light unit 12, and the warm white light unit 14 of the light emitting device 10 corresponding to FIG. 4B are the same as the blue light unit 11, the green light unit 12, and the warm white light unit 14 of the light emitting device 10 corresponding to FIG. 5B.

With reference to FIG. 3, FIG. 4A and FIG. 4B, when the red light unit 13 uses a blue chip to excite narrow-band nitride red phosphors and fluoride red phosphors, the light emitting device 10 can emit high-quality mixed white light with different color temperatures through the current configuration for four different light-emitting units.

TABLE 1
A color temperature adjustment solution that the red light unit 13
uses the blue chip to excite the narrow-band nitride red phosphors
and the fluoride red phosphors to realize CRI being greater than 90

| CCT | W | R (KSF) | G | B | x | y | CRI | R9 |
|---|---|---|---|---|---|---|---|---|
| 1800 | 35.5% | 64.5% | 0.0% | 0.0% | 0.5500 | 0.3998 | 92.4 | 66.2 |
| 2200 | 51.5% | 46.6% | 1.0% | 0.9% | 0.5052 | 0.4153 | 93.2 | 57.6 |
| 2700 | 56.8% | 34.8% | 4.9% | 3.5% | 0.4595 | 0.4105 | 92.8 | 58.8 |
| 3000 | 58.5% | 28.6% | 7.5% | 5.4% | 0.4347 | 0.4030 | 92.8 | 58.4 |
| 3500 | 58.5% | 23.0% | 10.9% | 7.6% | 0.4081 | 0.3919 | 92.9 | 58.5 |
| 4000 | 56.8% | 18.3% | 14.9% | 10.1% | 0.3818 | 0.3795 | 92.9 | 58.0 |
| 5000 | 52.4% | 12.6% | 20.5% | 14.5% | 0.3440 | 0.3545 | 93.2 | 59.3 |
| 5700 | 51.5% | 9.8% | 21.7% | 17.0% | 0.3279 | 0.3403 | 93.2 | 59.4 |
| 6500 | 48.5% | 7.7% | 24.5% | 19.3% | 0.3111 | 0.3263 | 93.3 | 60.4 |

TABLE 2
A color temperature adjustment solution that the red light unit 13 uses
the blue chip to excite the narrow-band nitride red phosphors and the
fluoride red phosphors to realize CRI being greater than or equal to 95

| CCT | W | R (KSF) | G | B | x | y | CRI | R9 |
|---|---|---|---|---|---|---|---|---|
| 2200 | 44.8% | 50.5% | 3.7% | 1.1% | 0.5046 | 0.4152 | 95.1 | 75.7 |
| 2700 | 50.0% | 38.8% | 7.7% | 3.5% | 0.4594 | 0.4098 | 95.9 | 78.4 |
| 3000 | 51.5% | 32.7% | 10.5% | 5.3% | 0.4344 | 0.4024 | 96.2 | 79.4 |
| 3500 | 51.5% | 27.1% | 13.9% | 7.4% | 0.4077 | 0.3912 | 96.2 | 80.7 |
| 4000 | 50.2% | 22.6% | 17.3% | 9.9% | 0.3815 | 0.3790 | 96.2 | 83.3 |
| 5000 | 46.2% | 16.5% | 23.3% | 13.9% | 0.3437 | 0.3541 | 95.7 | 84.9 |
| 5700 | 43.6% | 15.0% | 25.2% | 16.2% | 0.3273 | 0.3399 | 95.7 | 93.0 |
| 6500 | 41.4% | 12.4% | 27.8% | 18.4% | 0.3107 | 0.3259 | 95.8 | 93.3 |

Referring to Table 1 and Table 2, the light emitting device 10 provided by the embodiment of the present disclosure can adjust a color temperature and a CRI of mixed white light by setting a current ratio of each of the four light-emitting units. Specifically, a column marked by a correlated color temperature (CCT) in Table 1 and Table 2 represents a color temperature of the mixed white light close to the black body locus. Columns marked by W, R, G and B represent current ratios of the warm white light unit 14, the red light unit 13, the green light unit 12 and the blue light unit 11 respectively (calculated by taking a total current as 100%). Columns marked by x and y represent values of a color coordinate of the mixed white light in a CIE color space, a column marked by CRI represents CRI (Ra), and a column marked by R9 represents CRI (R9). Table 1 and Table 2 show that the light emitting device 10 provided by the embodiment of the present disclosure can provide mixed white light with a color temperature of 1800 K to 6500 K, a color rendering index CRI(Ra) of the mixed white light is greater than 90, and R9 can be kept to be greater than 50. Further, by adjusting the current ratios of the four light-emitting units, the mixed white light emitted by the light emitting device 10 is in a color temperature range of 2200 K to 6500 K, and a color rendering index CRI(Ra) of the mixed white light is greater than 95, and R9 is greater than 70.

With reference to FIG. 3, FIG. 5A and FIG. 5B, when the red light unit 13 uses a blue chip to excite wide-band nitride red phosphors, the light emitting device 10 can emit high-quality mixed white light with different color temperatures through current configuration (current ratio) for four different light-emitting units.

TABLE 3
A color temperature adjustment solution that red light unit 13 uses the blue chip
to excite the wide-band nitride red phosphors to realize CRI being greater than 90

| CCT | W | R | G | B | x | y | CRI | R9 |
|---|---|---|---|---|---|---|---|---|
| 1800 | 32.9% | 67.1% | 0.0% | 0.0% | 0.5435 | 0.4004 | 94.7 | 71.7 |
| 2200 | 49.2% | 48.2% | 1.8% | 0.8% | 0.5017 | 0.4155 | 91.6 | 54.7 |
| 2700 | 53.4% | 37.0% | 6.3% | 3.3% | 0.4577 | 0.4103 | 92.3 | 58.8 |
| 3000 | 55.1% | 31.1% | 8.6% | 5.2% | 0.4338 | 0.4036 | 91.9 | 58.1 |
| 3500 | 55.6% | 25.3% | 11.7% | 7.4% | 0.4077 | 0.3924 | 91.8 | 58.3 |
| 4000 | 55.3% | 19.8% | 15.1% | 9.8% | 0.3819 | 0.3799 | 91.3 | 56.2 |
| 5000 | 52.3% | 13.4% | 20.0% | 14.4% | 0.3449 | 0.3555 | 91.2 | 54.0 |
| 5700 | 51.1% | 10.8% | 21.2% | 16.8% | 0.3289 | 0.3421 | 91.0 | 55.0 |
| 6500 | 48.7% | 8.4% | 23.7% | 19.3% | 0.3124 | 0.3283 | 90.7 | 55.0 |

TABLE 4
A color temperature adjustment solution that red light unit
13 uses the blue chip to excite the wide-band nitride red
phosphors to realize CRI being greater than or equal to 95

| CCT | W | R | G | B | x | y | CRI | R9 |
|---|---|---|---|---|---|---|---|---|
| 2200 | 42.7% | 52.0% | 4.5% | 0.9% | 0.5016 | 0.4163 | 95.9 | 71.1 |
| 2700 | 47.7% | 40.5% | 8.3% | 3.4% | 0.4577 | 0.4101 | 95.9 | 73.8 |
| 3000 | 48.9% | 34.9% | 11.1% | 5.1% | 0.4340 | 0.4036 | 95.9 | 75.2 |
| 3500 | 49.2% | 29.2% | 14.3% | 7.2% | 0.4078 | 0.3921 | 95.8 | 77.1 |
| 4000 | 48.5% | 24.3% | 17.4% | 9.8% | 0.3818 | 0.3800 | 95.2 | 78.0 |
| 5000 | 44.0% | 19.1% | 23.2% | 13.8% | 0.3451 | 0.3557 | 95.6 | 85.0 |
| 5700 | 41.0% | 17.8% | 25.3% | 15.9% | 0.3289 | 0.3421 | 95.4 | 93.9 |
| 6500 | 38.6% | 15.5% | 27.9% | 18.1% | 0.3123 | 0.3286 | 95.0 | 95.6 |

As shown in Table 3 and Table 4, when the light emitting device 10 chooses wide-band nitride as a main light-emitting material for red light, CRI(Ra) of the mixed white light generated by the light emitting device 10 can still be greater than 90, and CRI(R9) of the mixed white light is greater than 50. By properly adjusting the current ratio of each light-emitting unit, when the color temperature of the mixed white light of the light emitting device 10 is between 2200 K and 6500 K as shown in Table 4, CRI(Ra) of the mixed white light can be greater than 95, and CRI(R9) of the mixed white light is also at a high level above 70.

Combining with FIG. 3 to FIG. 5B, and referring to Table 1 to Table 4, the present disclosure can realize the effect of adjusting color and color temperature and a higher CRI by designing four different light-emitting units with various current configurations, and the current ratios in the above tables are not used to limit the scope of protection of the present disclosure. In order to define the current configuration for obtaining the mixed white light with higher CRI, a color value K is defined for the mixed white light emitted by the light emitting device 10, which represents a ratio of a maximum luminous intensity at a wavelength of 480 nm to 540 nm to a minimum luminous intensity at a wavelength of 540 nm to 580 nm. The color value K is expressed by the following formula:

$$K = \frac{Max ( I ( {λ}_{1} ) )}{Min ( I ( {λ}_{2} ) )}$$

where λ₁ is greater than or equal to 480 nm and less than or equal to 540 nm, λ₂ is greater than or equal to 540 nm and less than or equal to 580 nm, and I represents a luminous intensity corresponding to light with a corresponding wavelength. When the color value K is within a preset range described in Table 5 through current configuration, the CRI of the mixed white light at a corresponding color temperature in a range of 1800 K to 6500 K can be greater than 90.

TABLE 5
Range of K when CRI is greater than or equal
to 90/95 at different color temperatures

| CCT | Kmin | Kmax |
|---|---|---|
| 1800 | 1.0 | 1.26 |
| 2200 | 1.0 | 1.18 |
| 2700 | 1.0 | 1.39 |
| 3000 | 1.0 | 1.46 |
| 3500 | 1.03 | 1.57 |
| 4000 | 1.11 | 1.71 |
| 5000 | 1.23 | 1.99 |
| 5700 | 1.27 | 2.08 |
| 6500 | 1.38 | 2.20 |

Furthermore, when the value of K is between a maximum value Kmax and a minimum value Kmin as shown in Table 5 above, the CRI of the mixed white light generated by the light emitting device 10 can be greater than or equal to 95 at a corresponding color temperature in a range of 2200 K to 6500 K.

In summary, the present disclosure provides the light emitting device, which includes the blue light unit for emitting the blue light, the green light unit for emitting the green light, the red light unit for emitting the red light and the warm white light unit for emitting the warm white light, which can be independently controlled, so as to realize the same dimming function of colored light and white light as the traditional RGBCW intelligent lamps. Especially, when a dominant wavelength of the warm white light is limited to be in a range from 570 nm to 600 nm, or a color coordinate W(x_{W}, y_{W}) of the warm white light is located above a Planckian locus and 0.4≤x_{W}≤0.5 and 0.4≤y_{W}≤0.5, the light emitting device can emit mixed white light closer to the black body locus in the process of color temperature adjustment.

Further, in order to realize high-quality mixed white light more easily, a dominant wavelength of the blue light is preferably 455 nm to 465 nm, a dominant wavelength of the green light is preferably 515 nm to 530 nm, and a dominant wavelength of the red light is preferably 615 nm to 630 nm.

Furthermore, in order to more easily realize that the CRI of the mixed white light is greater than 90 in the range of 1800 K to 6500 K, a normalized intensity of the warm white light at a wavelength of 530 nm is preferably between 25% and 75%. When the normalized intensity of the selected warm white light at a wavelength of 530 nm is controlled within 45% to 55%, the light emitting device can provide the mixed white light with CRI≥95 more stably and easily in a range of 2200 K to 6500 K.

In addition, it can be understood that the foregoing embodiments are merely exemplary explanations of the present disclosure, and the technical solutions of each embodiment can be combined and used at will on the premise that the technical features are not conflicting and contradictory, and do not violate the inventive purpose of the present disclosure.

Finally, it should be explained that the above embodiments are merely used to illustrate the technical solutions of the present disclosure, but not intended to limit the present disclosure. Although the present disclosure has been described in detail with reference to the foregoing embodiments, those skilled in the art should understand that it is still possible to modify the technical solution described in the foregoing embodiments, or to replace some technical features with equivalents. However, these modifications or substitutions do not make the essence of the corresponding technical solutions deviate from the spirit and scope of the technical solutions of various embodiments of the present disclosure.

What is claimed is:

1. A light emitting device, comprising:
a blue light unit, configured to emit blue light;
a green light unit, configured to emit green light;
a red light unit, configured to emit red light; and
a warm white light unit, configured to emit warm white light, wherein a dominant wavelength of the warm white light is in a range from 570 nm to 600 nm.

2. The light emitting device as claimed in claim 1, wherein a peak wavelength of the warm white light is in a range from 570 nm to 600 nm, and a full width at half maximum (FWHM) of the warm white light is in a range from 90 nm to 140 nm.

3. The light emitting device as claimed in claim 1, wherein a normalized intensity of the warm white light in a blue band is in a range from 10% to 30%.

4. The light emitting device as claimed in claim 1, wherein a normalized intensity of the warm white light at a wavelength of 530 nm is in a range from 25% to 75%.

5. The light emitting device as claimed in claim 1, wherein a color coordinate of the warm white light is expressed as W(x_{W}, y_{W}), where 0.4≤x_{W}≤0.5 and 0.4≤y_{W}≤0.5, and the color coordinate (W(x_{W}, y_{W})) of the warm white light is located above a Planckian locus.

6. The light emitting device as claimed in claim 1, wherein a dominant wavelength of the blue light is in a range from 455 nm to 465 nm, a dominant wavelength of the green light is in a range from 515 nm to 530 nm, and a dominant wavelength of the red light is in a range from 615 nm to 630 nm.

7. The light emitting device as claimed in claim 6, wherein the red light unit comprises a blue chip and wide-band nitride red phosphors, the blue chip is configured to excite the wide-band nitride red phosphors to emit the red light, a peak wavelength of the red light is 634±5 nm, and an FWHM of the red light is in a range from 70 nm to 90 nm.

8. The light emitting device as claimed in claim 7, wherein the wide-band nitride red phosphors are red phosphors with an FWHM of 70 nm to 90 nm.

9. The light emitting device as claimed in claim 1, wherein the blue light unit, the green light unit, the red light unit and the warm white light unit are configured to cooperate to emit mixed white light and are configured to adjust a color temperature of the mixed white light.

10. The light emitting device as claimed in claim 6, wherein the red light unit comprises a blue chip, narrow-band nitride red phosphors and a fluoride red phosphors, the blue chip is configured to excite the narrow-band nitride red phosphors and the fluoride red phosphors to emit the red light, a peak wavelength of the red light is 632±2 nm, and an FWHM of the red light is less than or equal to 10 nm.

11. The light emitting device as claimed in claim 10, wherein a dominant wavelength of the blue chip is in a range from 445 nm to 460 nm.

12. The light emitting device as claimed in claim 11, wherein the narrow-band nitride red phosphors are red phosphors with an FWHM of 60 nm to 70 nm.

13. The light emitting device as claimed in claim 12, wherein fluoride red phosphors comprise Mn⁴⁺-activated K₂TiF₆, K₂GeF₆, and K₂TiF₆.

14. The light emitting device as claimed in claim 1, wherein the blue light unit comprises a first blue chip with a dominant wavelength being greater than or equal to 455 nm and less than or equal to 465 nm, the green light unit comprises a green chip with a dominant wavelength being greater than or equal to 515 nm and less than or equal to 530 nm, the red light unit comprises a second blue chip with a dominant wavelength being greater than or equal to 445 nm and less than or equal to 460 nm, and the warm white light unit comprises a third blue chip with a dominant wavelength being greater than or equal to 445 nm and less than or equal to 460 nm.

15. The light emitting device as claimed in claim 14, wherein the warm white light unit further comprises yellow-green phosphors with a main emission band of 530 nm to 550 nm and red phosphors with a main emission band of 600 nm to 625 nm.

16. The light emitting device as claimed in claim 1, wherein a color coordinate of the warm white light unit and a color coordinate of the red light unit are respectively located at opposite sides of a Planckian locus.

17. The light emitting device as claimed in claim 16, wherein the color coordinate of the warm white light is expressed as W(x_{W}, y_{W}), where 0.4≤x_{W}≤0.5 and 0.4≤y_{W}≤0.5, and the color coordinate (W(x_{W}, y_{W})) of the warm white light is located above a Planckian locus;
wherein a color coordinate of the blue light unit is expressed as B(x_{B}, y_{B}), where 0.1≤x_{B}≤0.2, and 0≤y_{B}≤0.1;
wherein a color coordinate of the green light unit is expressed as G(x_{G}, y_{G}), where 0.1≤x_{G}≤0.2, and 0.65≤y_{G}≤0.75; and
wherein a color coordinate of the red light unit is expressed as R(x_{R}, y_{R}), where 0.63≤x_{R}≤0.7, and 0.3≤y_{R}≤0.35.

18. A light emitting device, comprising:
a blue light unit, comprising a first blue chip and configured to emit blue light;
a green unit, comprising a green chip and configured to emit green light;
a red light unit, comprising a second blue chip and configured to emit red light; and
a warm white light unit, comprising a third blue chip and configured to emit warm white light, a color coordinate of the warm white light is expressed as W(x_{W}, y_{w}), where 0.4≤x_{W}≤0.5 and 0.4≤y_{W}≤0.5, and the color coordinate W(x_{W}, y_{W}) of the warm white light is located above a Planckian locus;
wherein the blue light unit, the green light unit, the red light unit and the warm white light unit are configured to cooperate to emit mixed white light and are configured to adjust a color temperature of the mixed white light.

19. The light emitting device as claimed in claim 18, wherein a color coordinate of the blue light unit is expressed as B(x_{B}, y_{B}), where 0.1≤x_{B}≤0.2, and 0≤y_{B}≤0.1;
wherein a color coordinate of the green light unit is expressed as G(x_{G}, y_{G}), where 0.1≤x_{G}≤0.2, and 0.65≤y_{G}≤0.75;
wherein a color coordinate of the red light unit is expressed as R(x_{R}, y_{R}), where 0.63≤x_{R}≤0.7, and 0.3≤y_{R}≤0.35; and
wherein the color coordinate (W(x_{W}, y_{W})) of the warm white light unit and the color coordinate (R(x_{R}, y_{R})) of the red light unit are respectively located at opposite sides of the Planckian locus.

20. A light emitting device, comprising the blue light unit, the green light unit, the red light unit and the warm white light unit as claimed in claim 1;
wherein in a color temperature adjustment range of 1800 kelvins (K) to 6500 K, a color rendering index (CRI) of the mixed white light is greater than 90; or,
in a color temperature adjustment range of 2200 K to 6500 K, the CRI of the mixed white light is greater than or equal to 95.
